(19) United States
(12) Patent Application Publication
(10) Pub. No.: US 2007/0004212 A1
(43) Pub. Date: Jan. 4, 2007

(54) Method for manufacturing a semiconductor substrate and method for manufacturing a semiconductor device

(75) Inventors: Teruo Takizawa, Nagano-Ken (JP); Kei Kanemoto, Nagano-Ken (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/479,247

(22) Filed: Jun. 29, 2006

(30) Foreign Application Priority Data
Jun. 30, 2005 (JP) 2005-192034

(51) Int. Cl. H01L 21/311

(52) U.S. Cl. 438/694

(57) ABSTRACT

A method for manufacturing a semiconductor substrate comprises, forming a first semiconductor layer on a part of a surface of a semiconductor substrate, implanting a speed improvement factor to improve an etching speed and a diffusion inhibitor to inhibit diffusion of the speed improvement factor into the first semiconductor layer, forming a second semiconductor layer whose etching selective ratio is smaller than that of the first semiconductor layer on the first semiconductor layer, forming an insulating film on the semiconductor substrate to cover the second semiconductor layer, forming an opening face on the insulating film to partially expose an edge of the first semiconductor layer, etching the first semiconductor layer having the speed improvement factor and the diffusion inhibitor through the opening face so as to form a cavity under the second semiconductor layer, and forming an embedded oxide film in the cavity.

### BACKGROUND

1. Technical Field

The present invention relates to a method for manufacturing a semiconductor substrate and a method for manufacturing a semiconductor device. In particular, the invention relates to a technology to form a silicon-on-insulator (SOI) structure on a semiconductor substrate.

2. Related Art

Currently, development of SOI technology is carried out actively in the field of semiconductor manufacturing in order to provide integrated circuits with lower power consumption. Devices using an SOI substrate are known for providing characteristics allowing higher speed than those of devices in related art and low power consumption. This is because the devices can greatly reduce parasitic capacitance of transistors.

On the other hand, cost of the substrate is very high since special equipment is required in SIMOX method, a bonding method and so on for manufacturing the SOI substrate. The cost is normally 5 to 10 times more than that of a bulk substrate. Further, devices using the SOI structure have some disadvantages such as reduction of drain breakdown voltage and electrostatic discharge immunity level due to the special structure. In order to solve these problems, methods to form the SOI structure partially on a bulk substrate have been proposed.

One of the methods proposed as above is, as disclosed in Separation by Bonding Si islands (SBSI) for LSI Applications. (T, Sakai et al.), Second International SiGe Technology and Device Meeting Abstract, pp. 230-231, May(2004), SBSI technology. The SBSI technology is applicable to existing production lines for semiconductors in related art. Besides, the technology can provide an SOI device that can economically provide high-performance by allowing the SOI structure to form exclusively on a region where it is required on a bulk substrate.

To be specific, a SiGe layer and a Si layer are sequentially formed on a Si substrate by (selective) epitaxial growth. Then, only the SiGe layer is removed by etching from a lateral direction by making use of difference of an etching selective ratio between the Si layer and the SiGe layer to form a cavity between the Si substrate and the Si layer. The exposed silicon in the cavity is thermally oxidized and a SiO₂ layer is embedded between the Si substrate and the Si layer. This will be a BOX layer.

With the SBSI technology described above, the etching selective ratio between the Si layer and the SiGe layer is about 1:100 at most. Therefore, the Si layer is partially etched off besides the SiGe layer. That means, an etching selective ratio between a Si layer and a SiGe layer is limited and it is not possible to simply etch the Si layer broadly in a lateral direction without etching the Si layer. Thus a region of the SOI structure cannot be extended with the SBSI technology. (regarded as a problem)

### SUMMARY

An advantage of the invention is to provide a method for manufacturing a semiconductor substrate and a method for manufacturing a semiconductor device allowing a region of the SOI structure to extend.

According to a first aspect of the invention, a method for manufacturing a semiconductor substrate includes forming a first semiconductor layer on a part of a surface of a semiconductor substrate, implanting a speed improvement factor to improve an etching speed into the first semiconductor layer, forming a second semiconductor layer whose etching selective ratio is smaller than that of the first semiconductor layer on the first semiconductor layer, forming an insulating film on the semiconductor substrate to cover the second semiconductor layer, forming an opening face on the insulating film to partially expose an edge of the first semiconductor layer, etching the first semiconductor layer having the speed improvement factor through the opening face so as to form a cavity under the second semiconductor layer, and forming an embedded oxide film in the cavity.

The semiconductor substrate exemplified above is, for example, a bulk silicon (Si) substrate, and the first semiconductor layer is, for example, a silicon germanium (SiGe) layer gained by epitaxial growth. The second semiconductor layer is, for example, a Si layer gained by epitaxial growth. And the speed improvement factor is boron, for example.

According to the method for manufacturing a semiconductor substrate of the first aspect of the invention, the first semiconductor layer is rapidly etched off by the speed improvement factor when the cavity is formed, so that an etching selective ratio of the first semiconductor layer to the second semiconductor layer can improve. This makes it possible to etch exclusively the first semiconductor layer broadly to the lateral direction and prevent the second semiconductor layer from being etched so as to extend a region of the SOI structure.

According to a second aspect of the invention, a method for manufacturing a semiconductor substrate includes forming a first semiconductor layer on a part of a surface of a semiconductor substrate, implanting a speed improvement factor to improve an etching speed and a diffusion inhibitor to inhibit diffusion of the speed improvement factor into the first semiconductor layer, forming a second semiconductor layer whose etching selective ratio is smaller than that of the first semiconductor layer on the first semiconductor layer, forming an insulating film on the semiconductor substrate to cover the second semiconductor layer, forming an opening face on the insulating film to partially expose an edge of the first semiconductor layer, etching the first semiconductor layer having the speed improvement factor and the diffusion inhibitor through the opening face so as to form a cavity under the second semiconductor layer, and forming an embedded oxide film in the cavity.

In a case where a diffusion coefficient of the speed improvement factor in the first semiconductor layer is large, there is a risk that the speed improvement factor may diffuse to the second semiconductor layer above and the semiconductor substrate underneath at thermal treatment (e.g. a step to form the second semiconductor layer, a step to form the insulating film and a step to form the embedded oxide film) during the process.

According to the method for manufacturing a semiconductor substrate of the second aspect of the invention, the first semiconductor layer is rapidly etched off by the speed improvement factor when the cavity is formed. Further, since the diffusion inhibitor inhibits diffusion of the speed improvement factor to the second semiconductor layer and the semiconductor substrate, the second semiconductor layer is prevented from being etched rapidly. Therefore, compared to the first aspect of the invention, the etching selective ratio of the first semiconductor layer can improve further and only the first semiconductor layer can be etched off more broadly in the lateral direction. Therefore, it becomes possible to extend a region of the SOI structure on a semiconductor substrate.

In the second aspect of the invention, the speed improvement factor and the diffusion inhibitor may be implanted into the first semiconductor layer so as to match the distribution of the speed improvement factor and the distribution of the diffusion inhibitor in the first semiconductor layer.

In such a structure, diffusion of the speed improvement factor in the first semiconductor layer is inhibited. Therefore, diffusion of the speed improvement factor to the second semiconductor layer and the semiconductor substrate can be restrained effectively.

In the second aspect of the invention, the speed improvement factor and the diffusion inhibitor may be implanted into the first semiconductor layer so that the distribution of the diffusion inhibitor has peaks at both sides of a peak of the distribution of the speed improvement factor in the depth direction.

In the description above, the distribution of the diffusion inhibitor has peaks at both sides of a peak of the distribution of the speed improvement factor in the depth direction means at least 2 peaks of the distribution of the diffusion inhibitor in the depth direction should be formed and a peak of the distribution of the speed improvement factor should be between one peak and another peak among the peaks formed.

According to the method for manufacturing a semiconductor substrate, a distribution range of the speed improvement factor is almost limited to inside of the first semiconductor layer by the diffusion inhibitor that has peaks of the distribution at the both sides even after thermal treatment (e.g. a step to form the second semiconductor layer, a step to form the insulating film and a step to form embedded oxide film) during the process. Therefore, diffusion of the speed improvement factor to the second semiconductor layer and the semiconductor substrate can be restrained effectively.

In the second aspect of the invention, the speed improvement factor may be boron and the diffusion inhibitor may be carbon.

Here, boron typically tends to be diffused by thermal treatment via interstitial atoms (i.e. a region where energy level is low for boron). Further, carbon has a characteristic that can easily catch interstitial atoms.

According to the method for manufacturing a semiconductor substrate, in the first semiconductor layer including boron and carbon, the number of interstitial atoms is reduced and boron does not diffuse because of a few interstitial atoms by some thermal treatment. Therefore, most of boron can remain in the first semiconductor layer.

In the second aspect of the invention, a concentration of the carbon used as the diffusion inhibitor may be set in a range of 1*10¹⁷ to 1*10²² cm⁻³ in accordance with a concentration of the interstitial atoms in the first semiconductor layer.

In the description above, in accordance with a concentration of the interstitial atoms in the first semiconductor layer means to accord with a trend of various levels of concentration of the interstitial atoms. It means that carbon concentration can be set larger or smaller within the range above in accordance with the trend of concentration level of the interstitial atoms. It is not necessarily that the concentration value of the interstitial atoms should always match the concentration value of carbon.

For example, when the concentration value of the interstitial atoms is small, the value of carbon concentration shall be set around 10¹⁷ to 10¹⁸ cm⁻³. Alternatively, when the concentration value of the interstitial atoms is large, the value of carbon concentration shall be set around 10²¹ to 10²² cm⁻³. Further, when the concentration value is around the middle, the value of carbon concentration shall be set around 10¹⁹ to 10²⁰ cm−³.

In the second aspect of the invention, the diffusion inhibitor may be fluorine.

In the second aspect of the invention, forming a high-purity semiconductor layer on a surface of the semiconductor substrate prior to forming the first semiconductor layer is further included, and the first semiconductor layer may be formed on the high-purity semiconductor layer.

With such a structure, interstitial atoms inherent in the semiconductor substrate are prevented from diffusing directly to the first semiconductor layer by the high-purity semiconductor layer. Therefore, the number of the interstitial atoms in the first semiconductor layer can be minimized to the utmost extent.

According to a third aspect of the invention, a method for manufacturing a semiconductor device includes forming a first semiconductor layer on a part of a surface of a semiconductor substrate, implanting a speed improvement factor to improve an etching speed into the first semiconductor layer, forming a second semiconductor layer whose etching selective ratio is smaller than that of the first semiconductor layer on the first semiconductor layer, forming an insulating film on the semiconductor substrate to cover the second semiconductor layer, forming an opening face on the insulating film to partially expose an edge of the first semiconductor layer, etching the first semiconductor layer having the speed improvement factor through the opening face so as to form a cavity under the second semiconductor layer, forming an embedded oxide film in the cavity, and forming a transistor on the second semiconductor layer located on the embedded oxide film.

According to such a structure, the first semiconductor layer is rapidly etched off by the speed improvement factor when the cavity is formed. Therefore, an etching selective ratio of the first semiconductor layer to the second semiconductor layer can improve. This makes it possible to etch exclusively the first semiconductor layer broadly to the lateral direction and prevent the second semiconductor layer from being etched so as to extend a region of the SOI structure.

Thus many transistors having the SOI structure (hereinafter, referred to as SOI transistor) are enabled to be produced on a semiconductor substrate.

According to a fourth aspect of the invention, a method for manufacturing a semiconductor device includes forming a first semiconductor layer on a part of a surface of a semiconductor substrate, implanting a speed improvement factor to improve an etching speed and a diffusion inhibitor to inhibit diffusion of the speed improvement factor into the first semiconductor layer, forming a second semiconductor layer whose etching selective ratio is smaller than that of the first semiconductor layer on the first semiconductor layer, forming an insulating film on the semiconductor substrate to cover the second semiconductor layer, forming an opening face on the insulating film to partially expose an edge of the first semiconductor layer, etching the first semiconductor layer having the speed improvement factor and the diffusion inhibitor through the opening face so as to form a cavity under the second semiconductor layer, forming an embedded oxide film in the cavity, and forming a transistor on the second semiconductor layer located on the embedded oxide film.

With such a structure, the first semiconductor layer is rapidly etched off by the speed improvement factor when the cavity is formed. In addition, because the diffusion inhibitor inhibits diffusion of the speed improvement factor to the second semiconductor layer and the semiconductor substrate, the second semiconductor layer is prevented from being etched rapidly. Therefore, compared to the third aspect of the invention, the etching selective ratio of the first semiconductor layer can improve further and only the first semiconductor layer can be etched more broadly in the lateral direction.

This makes it possible to extend a region of the SOI structure and to form many SOI transistors on the semiconductor substrate. Further, because the first semiconductor layer is etched off sufficiently when the cavity is formed, particle generation is prevented. Accordingly, yield of the SOI transistor can be improved.

The invention is extremely suitable as it is applied to the SBSI technology to form an SOI structure exclusively on a region where it is required on a bulk semiconductor substrate.

### BRIEF DESCRIPTION OF THE DRAWINGS

The invention will be described with reference to the accompanying drawings, wherein like numbers reference like elements.

FIGS. 1A, 1B and 1C are diagrams illustrating a method for manufacturing a semiconductor device according to an embodiment of the invention.

FIGS. 2A, 2B and 2C are diagrams illustrating the method for manufacturing a semiconductor device according to the embodiment of the invention.

FIGS. 3A, 3B and 3C are diagrams illustrating the method for manufacturing a semiconductor device according to the embodiment of the invention.

FIGS. 4A, 4B and 4C are diagrams illustrating the method for manufacturing a semiconductor device according to the embodiment of the invention.

FIG. 5A is a diagram illustrating a first example of boron and carbon distributions right after being doped.

FIG. 5B is a diagram illustrating the first example of the boron and carbon distributions right after thermal treatment.

FIG. 6A is a diagram illustrating a second example of boron and carbon distributions right after being doped.

FIG. 6B is a diagram illustrating the second example of the boron and carbon distributions right after thermal treatment.

### DESCRIPTION OF EXEMPLARY EMBODIMENTS

Below, embodiments of the invention will now be described with reference to the accompanying drawings.

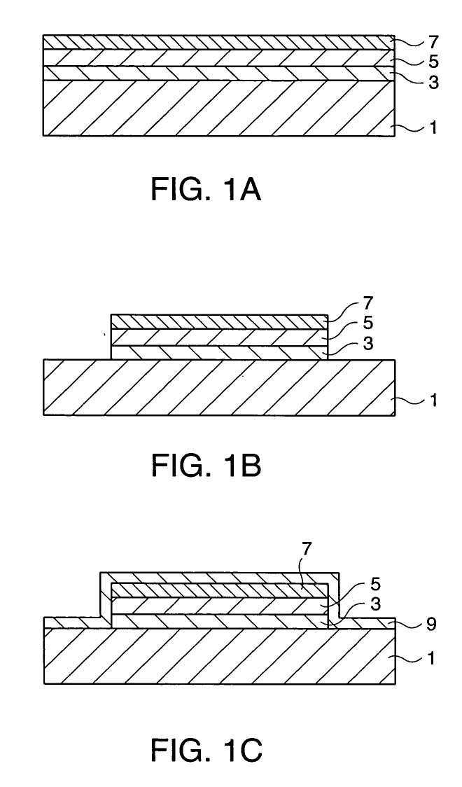

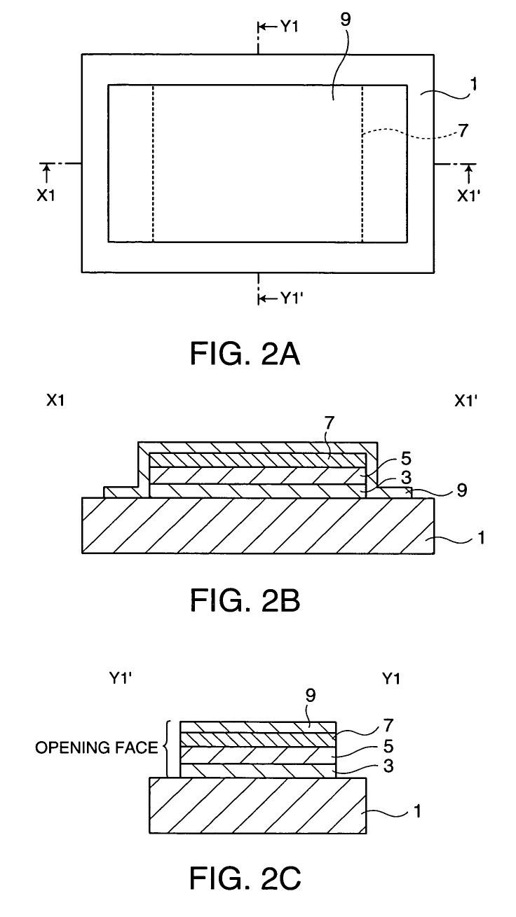

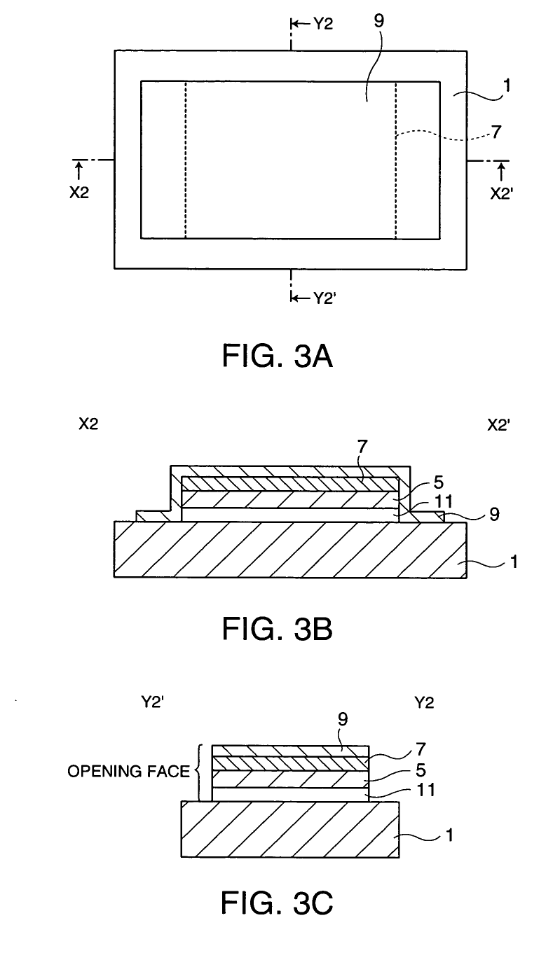

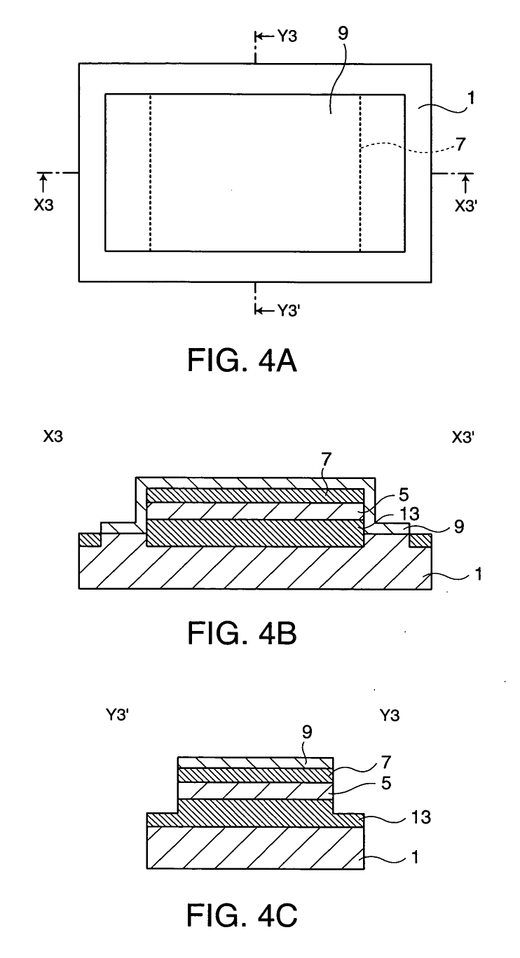

FIGS. 1A, 1B and 1C are sectional views showing a method for manufacturing a semiconductor device according to an embodiment of the invention. FIGS. 2A, 3A and 4A are plan views showing a method for manufacturing a semiconductor device according to the embodiment of the invention. FIG. 2B is a sectional view taken along the line X1-X1′ of FIG. 2A. FIG. 2C is a sectional view taken along the line Y1-Y1′ of FIG. 2A. FIG. 3B is a sectional view taken along the line X2-X2′ of FIG. 3A. FIG. 3C is a sectional view taken along the line Y2-Y2′ of FIG. 3A. FIG. 4B is a sectional view taken along the line X3-X3′ of FIG. 4A. FIG. 4C is a sectional view taken along the line Y3-Y3′ of FIG. 4A.

As shown in FIG. 1A, a sacrificial SiGe layer 3 that includes boron and carbon atoms is formed on a Si substrate 1 that is a bulk silicon wafer, and then a Si layer 5 is formed on the top thereof. The sacrificial SiGe layer 3 and the Si layer 5 are formed by epitaxial growth (or selective epitaxial growth).

By implanting boron into SiGe, a selective etching ratio of SiGe to Si is improved (SiGe becomes easy to be etched). However, a diffusion coefficient of boron is large in a semiconductor such as SiGe, and boron is easy to be diffused by thermal treatment during the process (e.g. an epitaxial growth of the Si layer 5, CVD and an oxidization process). Therefore, considering the thermal diffusion of boron, simply implanting boron into SiGe cannot be always expected to improve the selective ratio. Therefore, in the present embodiment, both boron and carbon are implanted into the sacrificial SiGe layer 3 at the epitaxial growth of the sacrificial SiGe layer 3.

Boron typically tends to be diffused by thermal treatment via interstitial atoms (i.e. a region where energy level is low for boron). Further, carbon has a characteristic that can easily catch interstitial atoms. Therefore, in the SiGe with boron and carbon, the number of the interstitial atoms is reduced by carbon. Since fewer interstitial atoms are included, boron is not diffused so much by some thermal treatment. Thus, most of boron continues to accumulate in the SiGe. It is preferable to set concentration of carbon in the SiGe at about 1*10¹⁷ to 1*10²² cm⁻³ in accordance with the density of the interstitial atoms. However, in the embodiment, the concentration of carbon in the SiGe is set at about 1*10¹⁹ to 1*10²⁰ cm⁻³. In addition, while carbon is used as a diffusion inhibitor for boron in the embodiment, the invention is not limited to this. As it is also reported that fluorine has a characteristic that catches interstitial atoms, an atom such as fluorine can be used as a diffusion inhibitor.

In sum, boron works as a speed improvement factor to improve an etching speed of the sacrificial SiGe layer 3 and carbon works as a diffusion inhibitor to inhibit boron diffusion. Therefore, even after some thermal treatment performed during the process, the sacrificial SiGe layer 3 including boron and carbon can keep the boron distribution as that before thermal treatments in the Si substrate 1 and the Si layer 5 located on and under the sacrificial SiGe layer 3. Epitaxial growth of the sacrificial SiGe layer 3 including boron and carbon is performed by using disilane gas, germane gas, diborane gas, dimethylsilane gas, for example. The concentration of boron is controlled by a flow rate of diborane gas and the concentration of carbon is controlled by a flow rate of dimethylsilane gas.

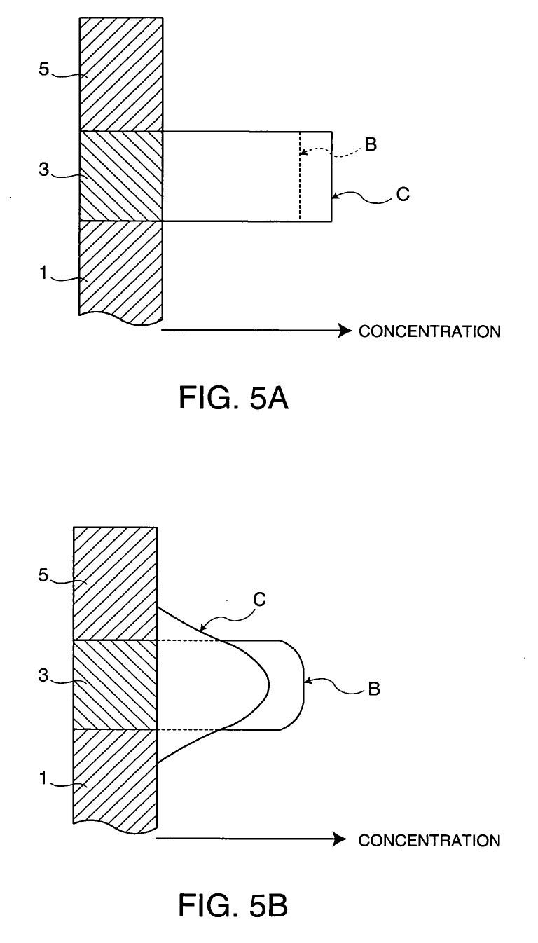

For the epitaxial growth of the sacrificial SiGe layer 3, the boron distribution and the carbon distribution shall be matched as shown in FIG. 5A by synchronizing the timing to flow diborane gas and dimethylsilane gas, for example. The thicknesses of the sacrificial SiGe layer 3 and the Si layer 5 are, for example, about 10 to 200 nm.

Next, as shown in FIG. 1A, a silicon oxide (SiO₂) film 7 is deposited on the sacrificial SiGe layer 3 by chemical vapor deposition (CVD) or the like. Then, as shown in FIG. 1B, the sacrificial SiGe layer 3, the Si layer 5 and the SiO₂ film 7 are patterned through a photolithography and an etching technique so as to expose the semiconductor substrate 1 except for an active region corresponding to an SOI structure.

Next, as shown in FIG. 1C, a supporting film 9 is formed on the whole surface of the Si substrate 1 by CVD or the like. This supporting film 9 is a film to support the Si layer 5 when the cavity is formed under the Si layer 5 and made of a silicon nitride film or a silicon oxide film, for example.

Then, as shown in FIGS. 2A through 2C, the supporting film is patterned through a photolithography and an etching technique so as to form an opening face to expose 2 sides (edges) of the sacrificial SiGe layer 3. In the case where 2 sides of the sacrificial SiGe layer 3 is exposed, the rest of the sides of the sacrificial SiGe layer 3 should remain to be covered with the supporting film 9.

Next, as shown in FIGS. 3A through 3C, the SiGe layer is etched off and removed by applying etchant such as the mixed acid of hydrofluoric acid and nitric acid to the sacrificial SiGe layer 3 and the Si layer 5 through the opening face formed on the supporting film 9 so as to form a cavity 11 between the Si substrate 1 and the Si layer 5.

In this step, the rest of the sides of the sacrificial SiGe layer 3 remain covered with the supporting film 9. Therefore, the Si layer 5 and the SiO₂ film 7 can keep the shape supported by the supporting film 9 on the Si substrate 1 even when the sacrificial SiGe layer 3 is removed.

FIG. 5B is a diagram showing an example of boron and carbon distributions after thermal treatment performed during the process. Carbon is diffused toward the Si substrate 1 and the Si layer 5 by thermal treatment after the sacrificial SiGe layer 3 is formed but before the cavity 11 is formed. However, thermal diffusion of boron is inhibited by carbon in the sacrificial SiGe layer 3. Therefore, boron is not diffused much toward the directions of the Si substrate 1 and the Si layer 5 as shown in FIG. 5B.

Accordingly, the sacrificial SiGe layer 3 is etched off rapidly, while the Si layer 5 is prevented from being etched rapidly in the step to form the cavity 11. Thus it is possible to etch exclusively the sacrificial SiGe layer 3 more broadly in a lateral direction in the step to form the cavity 11.

Next, the Si substrate 1 and the Si layer 5 are oxidized by thermal treatment. A SiO₂ film 13 is thus formed so as to fill the cavity between the Si substrate 1 and the Si layer 5 as shown in FIGS. 4A through 4C. In a case where the cavity is not filled with the SiO₂ film 13 sufficiently, a SiO₂ film or the like can be deposited in the cavity by CVD or the like after thermal oxidization.

Thereafter, an oxide film (not shown) is deposited on the whole surface of the Si substrate 1. Then, the oxide film is planarized by chemical mechanical polishing (CMP) so as to expose a surface of the Si layer 5. Next, a gate insulating film (not shown) is formed on the surface of the Si layer 5 by thermal oxdization of the surface of the Si layer 5. Then, a gate electrode (not shown) is formed on the Si layer 5 where the gate insulating film is formed. Further, a source region and a drain region (not shown) are formed by ion implantation of impurity such as As, P and B into the Si layer 5 using this gate electrode and so on as a mask so as to complete a SOI transistor on the Si substrate 1.

With such a method for manufacturing a semiconductor device according to the invention, the sacrificial SiGe layer 3 is etched rapidly by boron when the cavity 11 is formed. Moreover, boron diffusion to the Si layer 5 and the Si substrate 1 is inhibited by carbon, which can prevent the Si layer 5 from being etched rapidly. Accordingly, compared to the first aspect of the invention, further improvement of the etching selective ratio of the sacrificial SiGe layer 3 can be expected and the sacrificial SiGe layer 3 is exclusively etched off more broadly in a lateral direction.

This can provide a high selective ratio for SiGe selective etching, and a region of the SOI structure on the Si substrate 1 is allowed to extend. It becomes possible to form a large region of the SOI structure with fewer defects on a typical bulk wafer and thus more SOI transistors can be formed on the bulk wafer. Consequently, a mixed-signaled integrated circuit with both low power consumption and high breakdown voltage level is accomplished. To provide an economical device with low power consumption will become possible.

Further, since the sacrificial SiGe layer 3 is etched off sufficiently when the cavity 11 is formed, particle generation is prevented. Accordingly, yield of the SOI transistor can be improved.

In this embodiment, the Si substrate 1 corresponds to the semiconductor substrate of the invention, and the sacrificial SiGe layer 3 corresponds to the first semiconductor layer of the invention. Boron corresponds to the speed improvement factor of the invention, and carbon corresponds to the diffusion inhibitor of the invention. Further, the Si layer 5 corresponds to the second semiconductor layer of the invention, and the supporting film 9 corresponds to the insulating film of the invention. The SiO₂ film 13 corresponds to the embedded oxide film of the invention.

In this embodiment, a case is explained in which a boron distribution and a carbon distribution are matched as shown in FIG. 5A by synchronizing the timing to flow diborane gas and dimethylsilane gas when the sacrificial SiGe layer 3 is formed by epitaxial growth.

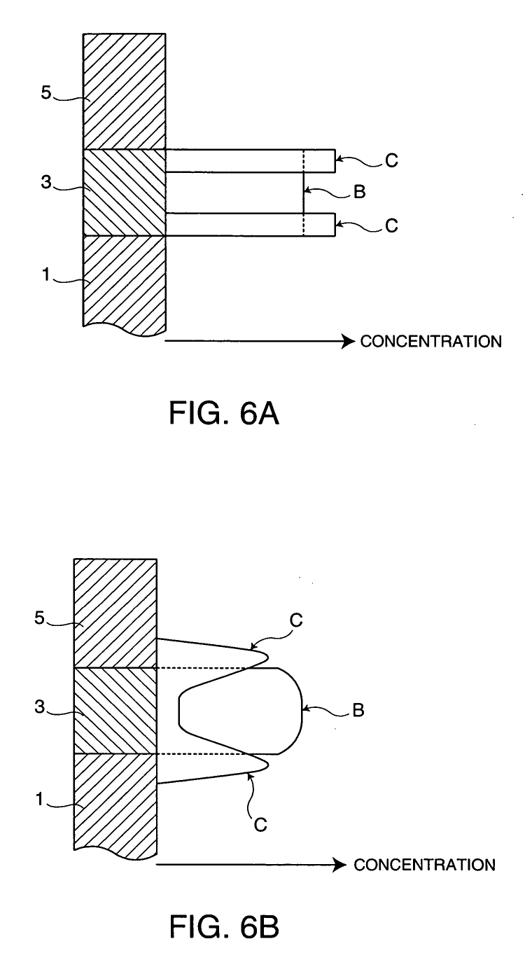

However, in a step to form this sacrificial SiGe layer 3, peaks of the carbon distribution may be positioned at both sides of a peak of the boron distribution in the depth direction as shown in FIG. 6A. To make this kind of difference of peaks is possible by performing modulation doping at epitaxial growth or delaying the timing to flow diborane gas or dimethylsilane gas, for example. In a case where the distribution is as shown in FIG. 6A, a diffusion range of boron is limited to inside of the sacrificial SiGe layer 3 by carbon that has peaks of the distribution at the both sides of boron after thermal treatment during the process as shown in FIG. 6B. Therefore, the boron diffusion to the Si layer 5 and the Si substrate 1 is restrained effectively.

In this embodiment, a case where the sacrificial SiGe layer 3 is directly formed on the Si substrate 1 is explained. However, it is possible to form a high-purity Si layer (corresponding to the high-purity semiconductor layer of the invention) between the Si layer 1 and the sacrificial SiGe layer 3 as a buffer layer alternatively. That is to say, a high-purity Si layer is formed on the Si substrate 1, and the sacrificial SiGe layer 3 is formed on the top. This high-purity Si layer is formed by epitaxial growth, for example.

With such a structure, direct diffusion of interstitial atoms from the Si substrate 1 to the sacrificial SiGe layer 3 is inhibited. Therefore, the number of interstitial atoms in the sacrificial SiGe layer 3 can be minimized to the utmost extent. Accordingly, boron diffusion can be inhibited even further.

In this embodiment, a case where a material of the semiconductor substrate is Si, a material of a first semiconductor layer is SiGe and a material of the second semiconductor layer is Si is explained. However, these materials are not limited to the above. Note that as a material for the semiconductor substrate, for example, Si, Ge, SiGe, SiC, SiSn, PbS, GaAs, InP, GaP, GaN or ZnSe can be used. As a material of the first semiconductor layer, a material whose etching selective ratio is larger than those of the Si substrate 1 and the second semiconductor layer can be used. For example, materials for the first semiconductor layer and the second semiconductor layer can be selected and combined from Si, Ge, SiGe, SiC, SiSn, PbS, GaAs, InP, GaP, GaN and ZnSe.

The entire disclosure of Japanese Patent application No. 2005-192034, field Jun. 30, 2005 is expressly incorporated by reference herein.

What is claimed is:

1. A method for manufacturing a semiconductor substrate, comprising:
forming a first semiconductor layer on a part of a surface of a semiconductor substrate;
implanting a speed improvement factor to improve an etching speed and a diffusion inhibitor to inhibit diffusion of the speed improvement factor into the first semiconductor layer;
forming a second semiconductor layer whose etching selective ratio is smaller than that of the first semiconductor layer on the first semiconductor layer;
forming an insulating film on the semiconductor substrate to cover the second semiconductor layer;
forming an opening face on the insulating film to partially expose an edge of the first semiconductor layer;
etching the first semiconductor layer having the speed improvement factor and the diffusion inhibitor through the opening face so as to form a cavity under the second semiconductor layer; and
forming an embedded oxide film in the cavity.

2. The method for manufacturing a semiconductor substrate according to claim 1, wherein the speed improvement factor and the diffusion inhibitor are implanted into the first semiconductor layer so as to match a distribution of the speed improvement factor and a distribution of the diffusion inhibitor in the first semiconductor layer.

3. The method for manufacturing a semiconductor substrate according to claim 1, wherein the speed improvement factor and the diffusion inhibitor are implanted into the first semiconductor layer so that the distribution of the diffusion inhibitor has peaks at both sides of a peak of the distribution of the speed improvement factor in a depth direction.

4. The method for manufacturing a semiconductor substrate according to claim 1, wherein the speed improvement factor is boron and the diffusion inhibitor is carbon.

5. The method for manufacturing a semiconductor substrate according to claim 1, wherein a concentration of the carbon used as the diffusion inhibitor is set in a range of 1*1017 to 1*1022 cm-³ in accordance with a concentration of an interstitial atom in the first semiconductor layer.

6. The method for manufacturing a semiconductor substrate according to claim 1, wherein the diffusion inhibitor is fluorine.

7. The method for manufacturing a semiconductor substrate according to claim 1, further comprising forming a high-purity semiconductor layer on a surface of the semiconductor substrate prior to forming the first semiconductor layer, wherein the first semiconductor layer is formed on the high-purity semiconductor layer.

8. A method for manufacturing a semiconductor device, comprising:
forming a first semiconductor layer on a part of a surface of a semiconductor substrate;
implanting a speed improvement factor to improve an etching speed into the first semiconductor layer;
forming a second semiconductor layer whose etching selective ratio is smaller than that of the first semiconductor layer on the first semiconductor layer;
forming an insulating film on the semiconductor substrate to cover the second semiconductor layer;
forming an opening face on the insulating film to partially expose an edge of the first semiconductor layer;
etching the first semiconductor layer having the speed improvement factor through the opening face so as to form a cavity under the second semiconductor layer;
forming an embedded oxide film in the cavity; and
forming a transistor on the second semiconductor layer located on the embedded oxide film.

9. A method for manufacturing a semiconductor device, comprising:
forming a first semiconductor layer on a part of a surface of a semiconductor substrate;
implanting a speed improvement factor to improve an etching speed and a diffusion inhibitor to inhibit diffusion of the speed improvement factor into the first semiconductor layer;
forming a second semiconductor layer whose etching selective ratio is smaller than that of the first semiconductor layer on the first semiconductor layer;
forming an insulating film on the semiconductor substrate to cover the second semiconductor layer;
forming an opening face on the insulating film to partially expose an edge of the first semiconductor layer;
etching the first semiconductor layer having the speed improvement factor and the diffusion inhibitor through the opening face so as to form a cavity under the second semiconductor layer;
forming an embedded oxide film in the cavity; and
forming a transistor on the second semiconductor layer located on the embedded oxide film.
